(19) United States
(12) Patent Application Publication
(10) Pub. No.: US 2013/0256895 A1
(43) Pub. Date: Oct. 3, 2013

(54) STACKED SEMICONDUCTOR COMPONENTS WITH UNIVERSAL INTERCONNECT FOOTPRINT

(71) Applicants: Michael Su, Round Rock, TX (US); Bryan Black, Spicewood, TX (US); Joe Siegel, Brookline, MA (US); Neil McLellan, Austin, TX (US); Michael Alfano, Austin, TX (US)

(72) Inventors: Michael Su, Round Rock, TX (US); Bryan Black, Spicewood, TX (US); Joe Siegel, Brookline, MA (US); Neil McLellan, Austin, TX (US); Michael Alfano, Austin, TX (US)

(21) Appl. No.: 13/436,124

(22) Filed: Mar. 30, 2012

(51) Int. Cl. H01L 23/538; H01L 21/768

(52) U.S. Cl. 257/773; 438/618; 257/E23.169; 257/E21.575

(57) ABSTRACT

A method of manufacturing is provided that includes fabricating a first set of interconnect structures on a side of a first semiconductor substrate. The first semiconductor substrate is operable to have at least one of plural semiconductor substrates stacked on the side. The first set of interconnect structures is arranged in a pattern. Each of the plural semiconductor substrates has a second set of interconnect structures arranged in the pattern, one of the plural semiconductor substrates has a smallest footprint of the plural semiconductor substrates. The pattern has a footprint smaller than the smallest footprint of the plural semiconductor substrates.

### BACKGROUND OF THE INVENTION

1. Field of the Invention

This invention relates generally to semiconductor processing, and more particularly to electrical interface structures for stacked semiconductor chips and to methods of assembling the same.

2. Description of the Related Art

Die stacking is a new technology that reduces interface power by reducing the physical distance between dies. Current die stacking technologies utilize physical interfaces, such as micro bumps, to transmit data, control signals, and power between adjacent dice. Some conventional die stacking arrangements incorporate multiple semiconductor chips stacked on a larger semiconductor chip. One example includes multiple DRAM chips stacked on a processor chip. Some of these conventional designs place a silicon interposer between the large die and the smaller dice. The silicon interposer is fitted with through-silicon-vias to connect the smaller dice electrically to the large die. In some cases, the lowermost small die connects to the interposer by way of multiple micro bumps.

Manufacturers or assemblers of stacked systems may look to multiple vendors to supply the smaller dice. Not surprisingly, different vendors of the same types of chips may use different design rules and standard cell layout libraries, and thus produce logically equivalent chips that have different substrate and micro bump footprints. This can necessitate the design and manufacture of multiple versions of an interposer for a given stack arrangement. There is a cost penalty associated with requiring multiple interposer designs.

Another issue associated with conventional stacked arrangements is die overhang If peripheral areas of a die stacked on an interposer are unsupported by micro bumps, due to mismatches between die and micro bump footprints, die overhangs can result. Such overhangs may be subjected to fracture due to asymmetric loadings.

The present invention is directed to overcoming or reducing the effects of one or more of the foregoing disadvantages.

### SUMMARY OF EMBODIMENTS OF THE INVENTION

In accordance with one aspect of an embodiment of the present invention, a method of manufacturing is provided that includes fabricating a first set of interconnect structures on a side of a first semiconductor substrate. The first semiconductor substrate is operable to have at least one of plural semiconductor substrates stacked on the side. The first set of interconnect structures is arranged in a pattern. Each of the plural semiconductor substrates has a second set of interconnect structures arranged in the pattern, one of the plural semiconductor substrates has a smallest footprint of the plural semiconductor substrates. The pattern has a footprint smaller than the smallest footprint of the plural semiconductor substrates.

In accordance with another aspect of an embodiment of the present invention, an apparatus is provided that includes a first semiconductor substrate that has a side and a first set of interconnect structures on the side and arranged in a pattern. The first semiconductor substrate is operable to have at least one of plural semiconductor substrates stacked on the side. Each of the plural semiconductor substrates has a second set of interconnect structures arranged in the pattern. One of the plural semiconductor substrates has a smallest footprint of the plural semiconductor substrates. The pattern has a footprint smaller than the smallest footprint of the plural semiconductor substrates.

In accordance with another aspect of an embodiment of the present invention, an apparatus is provided that includes a first semiconductor substrate that has a side and a first set of interconnect structures on the side and arranged in a pattern. The first semiconductor substrate is operable to have at least one of plural semiconductor substrates stacked on the side. Each of the plural semiconductor substrates has a second set of interconnect structures arranged in the pattern. One of the plural semiconductor substrates has a smallest footprint of the plural semiconductor substrates. The pattern has a footprint smaller than the smallest footprint of the plural semiconductor substrates. The at least one of the plural semiconductor substrates is stacked on the side and the second set of interconnect structures are coupled to the first set of interconnect structures.

### BRIEF DESCRIPTION OF THE DRAWINGS

The foregoing and other advantages of the invention will become apparent upon reading the following detailed description and upon reference to the drawings in which:

FIG. 1 is a sectional view of an exemplary embodiment of a semiconductor chip device that includes a semiconductor substrate and another semiconductor substrate mounted thereon;

FIG. 2 is a small portion of FIG. 1 shown at greater magnification;

FIG. 3 is a sectional view like FIG. 2, but depicting an alternate exemplary interconnect;

FIG. 4 is a sectional view like FIG. 2, but depicting another alternate exemplary interconnect;

FIG. 5 is a sectional view of FIG. 1 taken at section 5-5;

FIG. 6 is a pictorial view of an exemplary semiconductor substrate and three exemplary semiconductor substrates that may be stacked thereon;

FIG. 7 is a sectional view of a small portion of an exemplary semiconductor substrate undergoing barrier film processing;

FIG. 8 is a sectional view like FIG. 7, but depicting additional lithographic processing of the semicondutor substrate;

FIG. 9 is a sectional view like FIG. 8, but depicting fabrication of an exemplary interconnect structure;

FIG. 10 is a sectional view like FIG. 9, but depicting additional barrier film processing;

FIG. 11 is a sectional view like FIG. 10, but depicting exemplary stacking of a second semiconductor substrate on the first;

FIG. 12 is an exploded pictorial view depicting stacking of semiconductor substrates with a mesh frame for underfill application; and

FIG. 13 is a pictorial view showing an exemplary semiconductor chip device exploded from an exemplary electronic device.

### DETAILED DESCRIPTION OF SPECIFIC EMBODIMENTS

Various stacked semiconductor chip arrangements are disclosed. The disclosed embodiments incorporate a first semiconductor substrate that has a side and a first set of interconnect structures on the side and arranged in a pattern. The first semiconductor substrate is operable to have at least one of plural semiconductor substrates stacked on the side. Each of the plural semiconductor substrates has a second set of interconnect structures arranged in the pattern. One of the plural semiconductor substrates has a smallest footprint of the plural semiconductor substrates. The pattern has a footprint smaller than the smallest footprint of the plural semiconductor substrates. In this way, the first semiconductor substrate, implemented as an interposer or otherwise, has an interconnect set with a universal footprint capable of matching up with different sized dice fabricated with matching interconnect sets that share that universal footprint. Additional details will now be described.

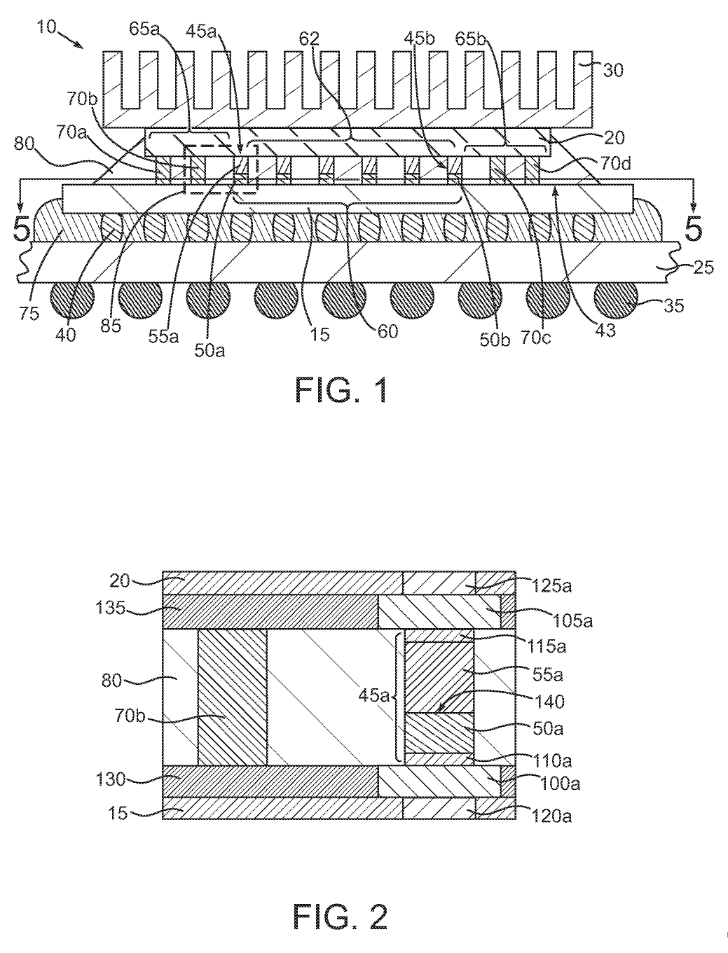

In the drawings described below, reference numerals are generally repeated where identical elements appear in more than one figure. Turning now to the drawings, and in particular to FIG. 1, therein is shown a sectional view of an exemplary embodiment of a semiconductor chip device 10 that includes a semiconductor substrate 15 and another semiconductor substrate 20 mounted thereon. The semiconductor substrate 15 may be mounted to a circuit board 25. A suitable heat sink 30 may be positioned on the semiconductor substrate 20 or any other structures thereon and constructed of well-known heat sink materials, such as copper, aluminum, stainless steel or others, and take on a variety of mechanical configurations.

None of the embodiments disclosed herein is reliant on particular functionalities of the semiconductor substrates 15 and 20 or the circuit board 25. Thus, the semiconductor substrates 15 and 20 may be any of a variety of different types of circuit devices used in electronics, such as, for example, interposers, microprocessors, graphics processors, combined microprocessor/graphics processors, application specific integrated circuits, memory devices or the like, and may be single or multi-core. The semiconductor substrates 15 and 20 may be constructed of bulk semiconductor, such as silicon or germanium, or semiconductor on insulator materials, such as silicon-on-insulator materials or even insulator materials. Thus, the term “semiconductor substrate” also contemplates insulating materials. In addition, any of the semiconductor substrates 15 and 20 may be configured as a semiconductor interposer, and thus as used herein, the terms “chip” and “substrate” are intended to encompass both semiconductor chips and interposers. Here, the semiconductor chip device 10 includes two semiconductor substrates 15 and 20 in a stack. However, more than two may be used.

The circuit board 25 may be another semiconductor chip of the type described above, a semiconductor chip package substrate, a circuit card, or virtually any other type of printed circuit board. Although a monolithic structure could be used for the circuit board 25, a more typical configuration will utilize a build-up design. In this regard, the circuit board 25 may consist of a central core upon which one or more build-up layers are formed and below which an additional one or more build-up layers are formed. The core itself may consist of a stack of one or more layers. So-called “coreless” designs may be used as well. The layers of the circuit board 25 may consist of an insulating material, such as various well-known epoxies or other resins interspersed with metal interconnects. A multi-layer configuration other than buildup could be used. Optionally, the circuit board 25 may be composed of well-known ceramics or other materials suitable for package substrates or other printed circuit boards.

Various types of electrical interconnects may be provided to establish electrical interconnection between the semiconductor substrate 15 and the circuit board 25 and the semiconductor substrate 20 and the semiconductor substrate 15 and between the circuit board 25 and some other electronic device not shown. For example, the depicted ball grid array 35 may be used to interface the circuit board 25 with some other electronic device (not shown). Optionally, other schemes, such as pin grid arrays, land grid arrays or other types of interconnect structures, may be used. Plural interconnect structures 40 may be provided between the semiconductor substrate 15 and the circuit board 25 and may be solder joints, conductive pillars plus solder or other types of interconnect structures as desired.

The semiconductor substrate 20 may be electrically interfaced with the semiconductor substrate 15 by way of the plural interconnects on a side 43 of the semiconductor substrate 15. Two of these interconnects are labeled 45a and 45b. The following description of the interconnects 45a and 45b will be illustrative of the others not labeled. The interconnect 45a may consist of a cooperating interconnect structure 50a of the semiconductor substrate 15 and an interconnect structure 55a of the semiconductor substrate 20. The interconnect 45b may similarly consist of an interconnect structure 50b of the semiconductor substrate 15 and an interconnect structure 55b of the semiconductor substrate 20. The interconnects 45a, 45b, etc. may be used to transmit power ground and/or signals and be constructed as micro bumps, conductive pillars plus solder or other types of interconnects. Exemplary materials include copper, aluminum, gold, platinum, palladium, silver, combinations of these or others. Additional details regarding the interconnect 45a and the interconnect 45b will be provided below.

Collectively, the interconnect structures 50a, 50b, etc., make up a set 60 of interconnect structures, and the interconnect structures 55a , 55b, etc., make up a cooperating set 62 of interconnect structures. Note that the interconnect sets 60 and 62 are not coextensive laterally with the semiconductor substrate 20. Thus the semiconductor substrate 20 has overhangs 65a and 65b that are lateral to the interconnect sets 60 and 62. To provide support for the overhangs 65a and 65b, support structures 70a, 70b, 70c and 70d may be provided at the periphery of the semiconductor substrate 20 and beneath the overhangs 65a and 65b. The skilled artisan will appreciate that the overhangs 65a and 65b may include the entire perimeter of the semiconductor substrate 20 as desired and thus there may be many more support structures other than the structures 70a, 70b, 70c and 70d depicted in FIG. 1. The support structures 70a, 70b, 70c and 70d are advantageously composed of various types of materials that can provide compliant structural support such as various types of polymers, such as well-known plastics, natural or synthetic rubbers or the like. Polymer materials may be screen printed or otherwise fabricated. Rubber support structures 70a, 70b, 70c and 70d may be drop placed.

To reduce the stresses associated with differences in the coefficients of thermal expansion among the semiconductor substrate 15 and the circuit board 25 and the semiconductor substrate 20, underfill material layers 75 and 80 may be provided between the semiconductor substrate 15 and circuit board 25 and between the semiconductor substrate 15 and the semiconductor substrate 20, respectively. The underfill material layers 75 and 80 may be composed of well-known types of underfill material. The underfill material layers 75 and 80 may be positioned by capillary action followed by a bake or in paste form in conjunction with a thermal compression bonding process.

The interconnect 45a and the support structure 70b will be used to illustrate additional features of those and related structures. The portion of FIG. 1 circumscribed by the dashed rectangle 85 will be shown at greater magnification in FIG. 2. As shown in FIG. 2 the interconnect structure 45a may include micro bumps 50a and 55a electrically connected to conductor pads 100a and 105a of the semiconductor substrates 15 and 20, respectively. In the event that the micro bumps 50a and 55a are composed of gold or a like material that will benefit from the usage of barrier films, a barrier film 110a may be formed between the micro bump 50a and the underlying conductor pad 100a and a corresponding barrier film 115a may be fabricated between the micro bump 55a and the conductor pad 105a. The barrier films 110a and 115a may be fabricated from materials that can act as barriers to diffusion and that adhere to the micro bumps 50a and 55a. Examples include tantalum and tantalum nitride. The conductor pads 100a and 105a may be electrically connected to other portions of the semiconductor substrates 15 and 20, respectively, in a variety of ways, such as, for example, by the thru-silicon vias (TSV) 120a and 125a. Since the semiconductor substrates 15 and 20 may be constructed of other than silicon, the term “TSV” is intended to include materials in addition to silicon. Optionally, other types of interconnect structures, such as multi-level metallization with conductive vias or other types of electrical pathways may be used. The micro bumps 50a and 55a, the conductor pads 100a, 105a and the TSVs 120a and 125a may be composed of a variety of conducting materials, such as copper, aluminum, gold, silver, platinum, palladium, combinations of these or the like.

The conductor pads 100a and 105a may be surrounded laterally by dielectric layers 130 and 135, which may be interlevel dielectric layers or other types of insulating layers composed of a variety of materials, such as silicon dioxide, silicon nitride, polyimide, tetra-ethyl-ortho-silicate or others. In the illustrative embodiment depicted in FIG. 2, the micro bumps 50a and 55a may be bonded at the interface 140 by thermal compression bonding. Where the underfill 80 is used, successful capillary dispensing may require a minimum spacing between the semiconductor substrates 15 and 20 on the order of 50 microns depending on device geometry and the density of the interconnects 45a and the others shown in FIG. 1. Where the underfill 80 is not used, the spacing can be closer to 10 microns, again depending on device geometry. The support structure 70b may be formed or placed on either of the semiconductor substrates 15 and 20 prior to stacking thereof.

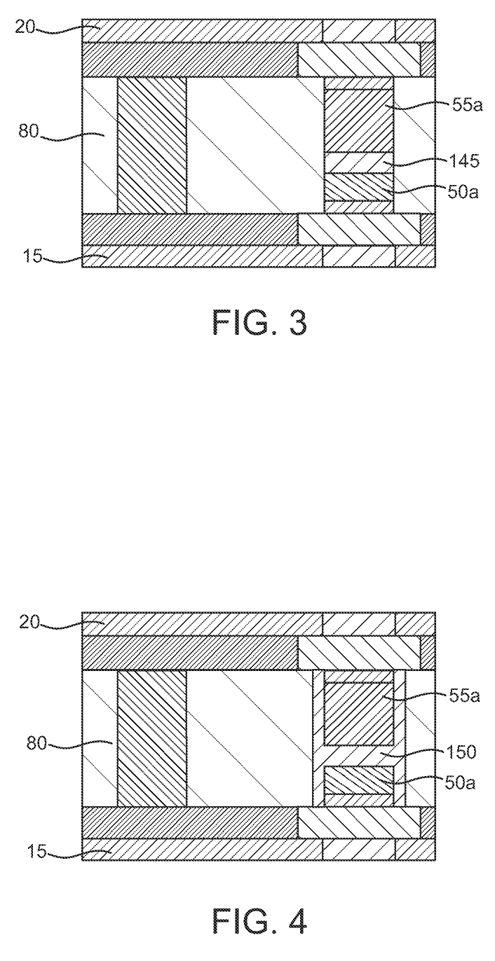

Optionally, other types of joining techniques may be used to connect the micro bumps 50a and 55a of the semiconductor chips 15 and 20, respectively. For example, and as shown in FIG. 3, the micro bumps 50a and 55a may be joined by a solder interface 145. The solder interface 145 may be the metallurgical combination of respective solder portions that are initially formed on the micro bumps 50a and 55a that are later joined together in a reflow process, optionally, a single solder cap may be placed on one or the other of the micro bumps 50a and 55a and thereafter a suitable reflow process used to establish the solder interface 145. Various lead or lead-free solders may be used, such as tin-lead (about 63% Sn and 37% Pb), tin-silver (about 97.3% Sn 2.7% Ag), tin-copper (about 99% Sn 1% Cu), tin-silver-copper (about 96.5% Sn 3% Ag 0.5% Cu) or the like. Again, the underfill 80 is optional.

In still another alternative shown in section in FIG. 4, solder cladding 150 may be used to establish a metallurgical bond between the micro bumps 50a and 55a of the semiconductor substrates 15 and 20, respectively. The solder cladding 150 may be composed of the solders described above. The underfill 80 is optional.

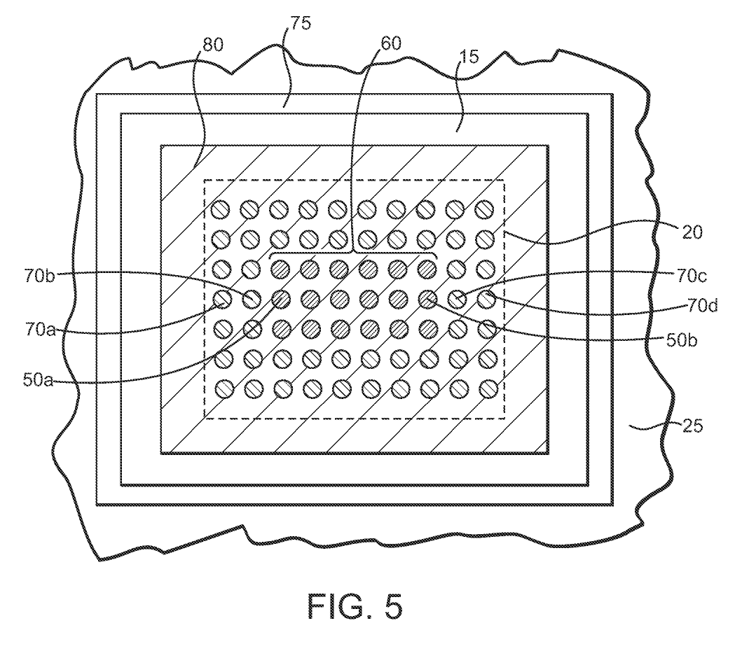

Additional details of the semiconductor substrate 15 may be understood by referring now to FIG. 5, which is a sectional view of FIG. 1 taken at section 5-5. Before turning to FIG. 5, it should be noted that section 5-5 passes through the interconnect set 60, and particularly the interconnect structures 50a and 50b, as well as the support structures 70a, 70b, 70c and 70d and others like them not separately labeled. Note that the support structures 70a, 70b, 70c and 70d and the interconnect set 60 and in particular the interconnect structures 50a and 50b are shown in section as well as the underfill 80. However, the portion of the semiconductor substrate 15 not covered by the underfill 80 is visible as well as the perimeter portion of the underfill 75 and a portion of the circuit board 25. The interconnect set 60 is designed to have a universal footprint in terms of the number of interconnects 50a, 50b, etc., the sizes and the spacing thereof, that will provide requisite electrical functionality for various types of semiconductor substrates or chips that may be stacked thereon, such as, for example, the semiconductor substrate 20, regardless of the actual footprint(s) of the additional substrates or chips. For example, the semiconductor substrate 20 (while not technically visible in FIG. 5) is depicted as a dashed box to show the relationship between the universal footprint of the interconnect set 60 and the footprint of the semiconductor substrate 20. By using a universal footprint for the interconnect set 60, multiple types of semiconductor chips or substrates with multiple footprints may be accommodated by using a common interconnect set footprint. Note also that the support structures 70a, 70b, 70c and 70d may be positioned around the entire perimeter of the semiconductor substrate 20 or where ever such support is needed. Note also that the interconnect set 60 need not be a symmetric structure as shown but may include interconnects at different locations.

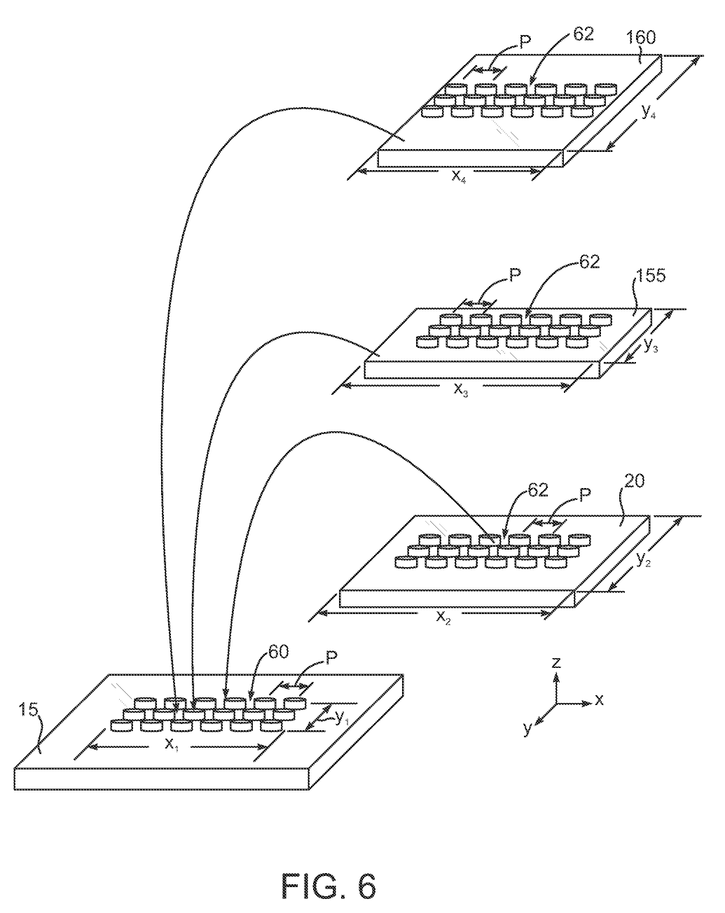

To illustrate stacking of multiple semiconductor substrates of different footprints on the semicondutor substrate 15 with the aforementioned interconnect set 60 with a common footprint, attention is now turned to FIG. 6, which is a pictorial view of the semiconductor substrate 15 and three exemplary semiconductor substrates that may be stacked on the semiconductor substrate 15. For simplicity of illustration, the optional support structures 70a, 70b, 70c and 70d shown in other figures are not illustrated. The three exemplary semiconductor substrates include the semiconductor substrate 20 discussed elsewhere herein, and two other semiconductor substrates 155 and 160. The semiconductor substrates 20, 155 and 160 are shown flipped over from their stacking orientation. The semiconductor substrates 155 and 160 both may be constructed of the same materials and have the same logical functions as the semiconductor substrate 20. Here the interconnect set 60 of the semiconductor substrate 15 has a pattern, and the pattern has a footprint x₁ by y₁. The pattern may be a regular array based on a selected interconnect structure pitch P, some other metric, or consist of some other type of pattern. The semiconductor substrate 20 has a footprint x₂ by y₂ and the interconnect set 62 that has the same pattern as the interconnect set 60. The semiconductor substrate 155 has a footprint x₃ by y₃, but the interconnect set 62 that also shares the pattern of the interconnect set 60. The semiconductor substrate 160 has a footprint x₄ by y₄, but the interconnect set 62 that also shares the pattern of the interconnect set 60. Note that the footprints x₂ by y₂, x₃ by y₃ and x₄ by y₄ may all differ from one another, and one, perhaps x₃ by y₃ will be the smallest. Indeed, the footprint x₃ by y₃ might be the smallest anticipated footprint available in the industry in a given period and for a particular type of device, i.e., memory, processor, ASIC etc. The footprint x₁ by y₁ of the interconnect set 60 is selected to be smaller than the smallest anticipated substrate footprint, say x₃ by y₃ for the substrate 155, the semiconductor substrate 15 can serve as a stacking platform for multiple substrate footprints, x₂ by y₂, x₃ by y₃ and x₄ by y₄. Of course, metrics other than x-y coordinates may be used to define the footprints x₁ by y₁, x₂ by y₂, x₃ by y₃ and x₄ by y₄. To the extent that there is overhang between the footprints of the semiconductor substrates 155 and 160, support structures 70a, 70b, 70c and 70d as disclosed elsewhere herein may be used (see FIG. 1).

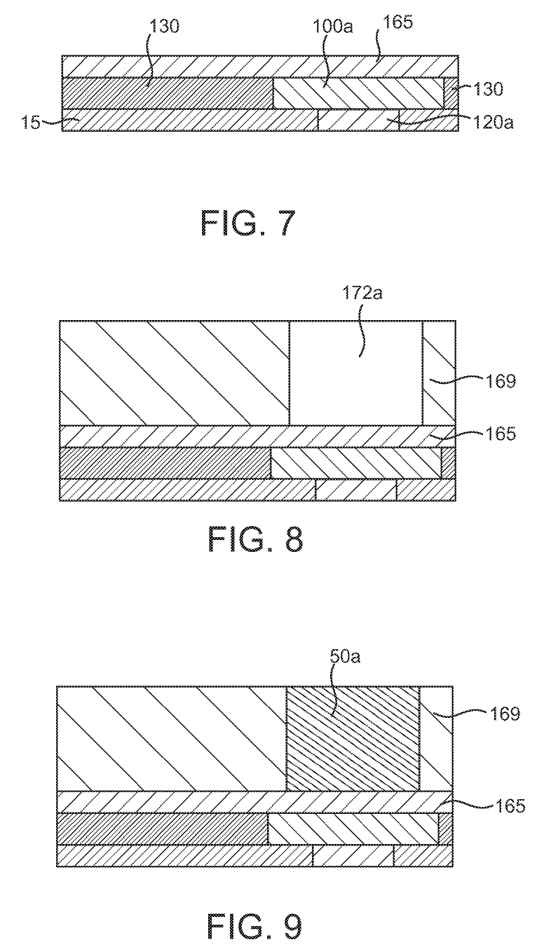

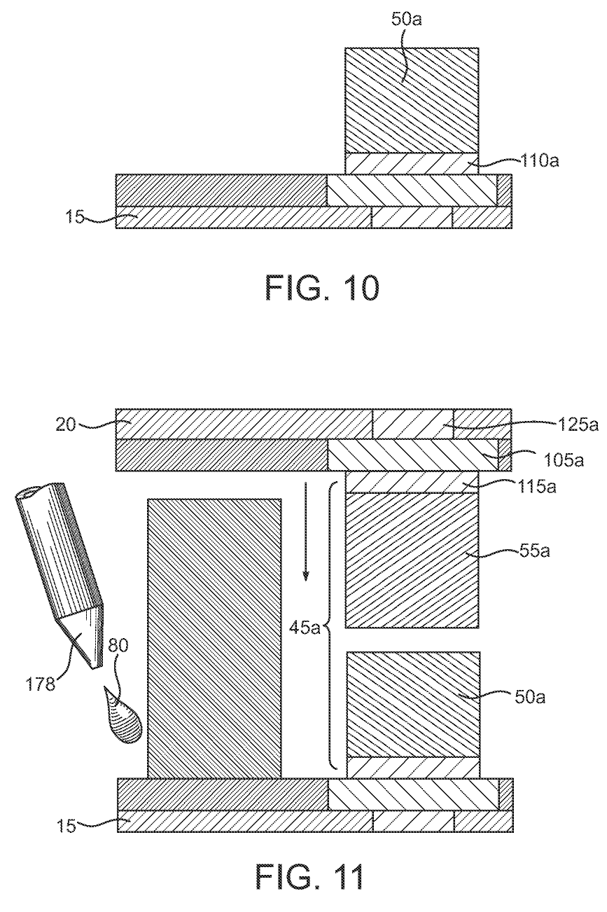

An exemplary method for fabricating the interconnect 45a and the support structure 70b may be understood by referring now to FIGS. 7, 8, 9, 10 and 11, and initially to FIG. 7. The following description of the fabrication of the interconnect 45a and the support structure 70b will be illustrative of the interconnects 45b and the support structures 70a, 70c and 70d depicted in FIGS. 1 and 2. It should be understood that the processing may be performed at the wafer or die level. Note that FIG. 7 depicts the small portion of the semiconductor substrate 15 depicted earlier in FIG. 2. Here, a small portion of the TSV 120a and the conductor pad 100a are visible along with the interlevel dielectric layer 130. At this stage, the TSV 120a and the conductor pad 100a have been constructed using well-known techniques such as plating, chemical vapor deposition (CVD), physical vapor deposition (PVD or sputtering) or the like. A blanket barrier film 165 that will be ultimately patterned into the barrier films 110 depicted in FIG. 2 is initially blanket deposited by PVD, CVD or other techniques.

Referring now to FIG. 8, a suitable lithography mask 169 may be formed on the barrier film 165 and patterned with a suitable opening 172a. Next and as shown in FIG. 9, a material deposition process may be used to establish the interconnect structure 50a on the barrier film 165 using the lithography mask 169. A variety of techniques may be suitable to form the interconnect structure 50a. In an exemplary embodiment, flash gold plating may be used. Following the application of the interconnect structure 50a, the lithography mask 169 may be stripped as shown in FIG. 9 and a suitable etch process used to etch the barrier film 165 shown in FIG. 8 using the electrically interconnect structure 50a as an etch mask to define the barrier film portion 110a.

At this stage, the semiconductor substrate chip 15 is ready to be stacked with the semiconductor substrate 20 as shown in FIG. 11. Prior to stacking, the support structure 70b is preferably fabricated or placed on either of the semiconductor substrates 15 and 20. It should be noted that the semiconductor substrate 20 has been provided with the interconnect structure 55a, the conductor pad 105a, the barrier film 115a and the TSV 125a using the same types of techniques just described for the interconnect structure 50a. It should also be noted that the other interconnect structures, such as 55b and the others not separately labeled in FIG. 1, have been formed with a layout or footprint that matches the common footprint of the interconnect set 60 of the semiconductor substrate 15. The semiconductor substrate 20 is moved into proximity with the semiconductor substrate 15 so that the interconnect structures 50a and 55a are touching or otherwise close enough to be subjected to thermal compression bonding. Following the thermal compression bonding, the interconnect 45a consisting of the interconnect structures 50a and 55a is established. The underfill material 80 may be dispensed between the semiconductor substrates 15 and 20 using a suitable applicator 178. After dispensing, the underfill 80 may undergo one or more bake processes to establish cure. Of course, dispensing of the underfill 80 may precede thermal compression bonding if that technique is used. If solder caps or cladding are used for bonding, then appropriate reflows may be performed to secure the interconnect structures 50a and 55a.

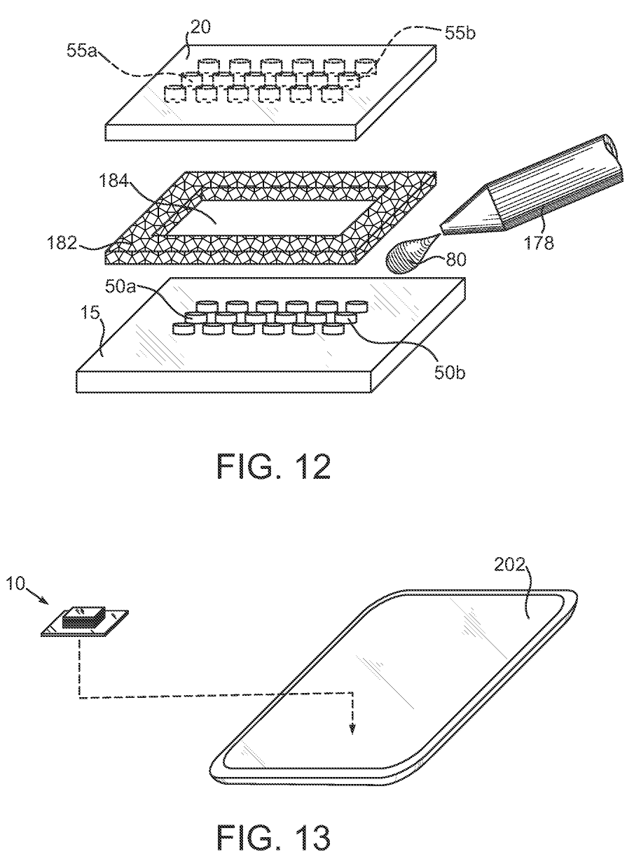

In lieu of capillary action, an underfill material may be applied as a non-conducting paste (NCP) and particularly where thermal compression bonding is used to establish bonding between the interconnect structures of the semiconductor substrate 15 and the overlying semiconductor substrate 20. In this regard, attention is now turned to FIG. 12, which is an exploded pictorial view showing the semiconductor substrate 15, the semiconductor substrate 20 and the interconnect structures 50a, 50b etc. of the semiconductor substrate 15 and the cooperating interconnect structures 55a, 55b, etc. that cooperatively bond when joined. Here, the underfill material 80 may be dispensed from the applicator 178 in NCP form. Prior to application of the NCP underfill 80, a suitable mesh frame 182 that includes a central opening 184 sized to accommodate the interconnect structures 50a, 50b, etc. may be positioned on a semiconductor substrate 15. Thereafter, the NCP underfill 80 may be applied and thermal compression bonding used to join the interconnect structures 50a, 50b, etc. to the corresponding interconnect structures 55a, 55b, etc. The mesh frame 182 may be composed of a variety of materials such as, for example, well-known plastics.

It should be understood that NCP and even a non-conducting film (NCF) may be used with or without the mesh 182 frame. It may also be possible to combine NCP and NCF. A NCP could be used nearer central regions and a NCF at the perimeters of the semiconductor substrates 15 and 20.

Any of the disclosed embodiments of the semiconductor chip device may be incorporated into another electronic device such as the electronic device 202 depicted in FIG. 13. Here, the semiconductor chip device 10 is shown exploded from the electronic device 202. The electronic device 202 may be a computer, a server, a hand held device, or virtually any other electronic component.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of manufacturing, comprising:
fabricating a first set of interconnect structures on a side of a first semiconductor substrate, the first semiconductor substrate being operable to have at least one of plural semiconductor substrates stacked on the side; and
whereby the first set of interconnect structures being arranged in a pattern, each of the plural semiconductor substrates having a second set of interconnect structures arranged in the pattern, one of the plural semiconductor substrates having a smallest footprint of the plural semiconductor substrates, the pattern having a footprint smaller than the smallest footprint of the plural semiconductor substrates.

2. The method of claim 1, wherein the first semiconductor substrate comprises a semiconductor chip.

3. The method of claim 1, wherein the first semiconductor substrate comprises an interposer.

4. The method of claim 1, comprising coupling plural support structures on the side adapted to engage an opposing side of the at least one of the plural semiconductor substrates.

5. The method of claim 1, comprising coupling a support frame on the side surrounding the first set of interconnect structures and being adapted to engage an opposing side of the at least one of the plural semiconductor substrates.

6. The method of claim 1, comprising stacking the at least one of the plural semiconductor substrates on the side.

7. The method of claim 6, wherein coupling the first and second sets of interconnect structures by thermal compression bonding.

8. The method of claim 6, wherein the at least one of the plural semiconductor substrates comprises a semiconductor chip.

9. The method of claim 1, comprising coupling the first semicondutor substrate to a circuit board.

10. An apparatus, comprising:
a first semiconductor substrate having a side; and
a first set of interconnect structures on the side and being arranged in a pattern; and
whereby the first semiconductor substrate is operable to have at least one of plural semiconductor substrates stacked on the side, each of the plural semiconductor substrates having a second set of interconnect structures arranged in the pattern, one of the plural semiconductor substrates having a smallest footprint of the plural semiconductor substrates, the pattern having a footprint smaller than the smallest footprint of the plural semiconductor substrates.

11. The apparatus of claim 10, wherein the first semiconductor substrate comprises a semiconductor chip.

12. The apparatus of claim 10, wherein the first semiconductor substrate comprises an interposer.

13. The apparatus of claim 10, comprising plural support structures on the side adapted to engage an opposing side of the at least one of the plural semiconductor substrates.

14. The apparatus of claim 10, comprising a support frame on the side surrounding the first set of interconnect structures and being adapted to engage an opposing side of the at least one of the plural semiconductor substrates.

15. The apparatus of claim 10, comprising the at least one of the plural semiconductor substrates stacked on the side.

16. The apparatus of claim 15, wherein the first and second sets of interconnect structures are coupled by thermal compression bonding.

17. The apparatus of claim 15, wherein the at least one of the plural semiconductor substrates comprises a semiconductor chip.

18. An apparatus, comprising:
a first semiconductor substrate having a side and a first set of interconnect structures on the side and being arranged in a pattern, the first semiconductor substrate being operable to have at least one of plural semiconductor substrates stacked on the side, each of the plural semiconductor substrates having a second set of interconnect structures arranged in the pattern, one of the plural semiconductor substrates having a smallest footprint of the plural semiconductor substrates, the pattern having a footprint smaller than the smallest footprint of the plural semiconductor substrates; and
the at least one of the plural semiconductor substrates stacked on the side, the second set of interconnect structures being coupled to the first set of interconnect structures.

19. The apparatus of claim 18, wherein the first semiconductor substrate comprises a semiconductor chip.

20. The apparatus of claim 18, wherein the first semiconductor substrate comprises an interposer.

21. The apparatus of claim 18, comprising plural support structures on the side adapted to engage an opposing side of the at least one of the plural semiconductor substrates.

22. The apparatus of claim 18, comprising a support frame on the side surrounding the first set of interconnect structures and being adapted to engage an opposing side of the at least one of the plural semiconductor substrates.

23. The apparatus of claim 18, wherein the first and second sets of interconnect structures are coupled by thermal compression bonding.

24. The apparatus of claim 18, wherein the at least one of the plural semiconductor substrates comprises a semiconductor chip.
